(19) United States
(12) Patent Application Publication
(10) Pub. No.: US 2023/0413642 A1
(43) Pub. Date: Dec. 21, 2023

(54) DISPLAY PANEL AND ELECTRONIC DEVICE

(71) Applicant: Shanghai Tianma Micro-Electronics Co., Ltd., Shanghai (CN)

(72) Inventor: Yang ZENG, Shanghai (CN)

(73) Assignee: Shanghai Tianma Micro-Electronics Co., Ltd., Shanghai (CN)

(21) Appl. No.: 18/461,539

(22) Filed: Sep. 6, 2023

(30) Foreign Application Priority Data
Jun. 15, 2023 (CN) 202310715236.2

(51) Int. Cl. H10K 59/80; H10K 59/121; H10K 59/35

(52) U.S. Cl. CPC H10K 59/80515; H10K 59/1213; H10K 59/35

(57) ABSTRACT

A display panel and an electronic device are provided. The display panel includes a display area. The display area includes a first display area and a second display area at least partially surrounds the first display area. The first display area has greater light transmittance than the second display area. The display panel further includes a substrate, and a display array on the substrate. The display array includes light emitting elements arranged in the display area. The light emitting elements arranged in the first display area are grouped into at least one light emitting element group. The light emitting elements in the same light emitting element group share a same anode, and therefore are controlled to emit light synchronously via the anode, to decrease a lightproof structure in the first display area in size and improving the light transmittance of the first display area.

The present application claims the priority to Chinese Patent Application No. 202310715236.2, titled “DISPLAY PANEL AND ELECTRONIC DEVICE”, filed on Jun. 15, 2023 with the China National Intellectual Property Administration, which is incorporated herein by reference in its entirety.

### FIELD

The present application relates to the field of electronic devices, and in particular a display panel and an electronic device.

### BACKGROUND

In emerging science and technologies, electronic devices capable of displaying objects are increasingly used in daily life and work, greatly facilitating daily life and work, and have become indispensable tools.

A main component that is capable of displaying objects on the electronic device is a display panel. The display panel is provided with an area with high light transmittance, for arranging photosensitive elements such as under-screen cameras and optical sensors, in order to acquire light. However, the light transmittance in this area is still low due to a lightproof structure in the display panel.

### SUMMARY

In view of this, a display panel and an electronic device are provided according to embodiments of the present application. The solutions are as follows.

A display panel is provided according to the embodiments of the present application. The display panel includes a display area. The display area includes a first display area and a second display area at least partially surrounding the first display area. The first display area has greater light transmittance than the second display area. The display panel further includes a substrate, and a display array on the substrate. The display array includes light emitting elements arranged in the display area. The light emitting elements arranged in the first display area are grouped into at least one light emitting element group. The light emitting elements in the same light emitting element group share a same anode.

An electronic device is also provided according to the embodiments of the present application. The electronic device includes the display panel, a photosensitive component and a control chip. The display panel includes a display area, a substrate and a display array. The display area includes a first display area and a second display area at least partially surrounding the first display area. The display array includes light emitting elements arranged in the display area. The light emitting elements arranged in the first display area are grouped into at least one light emitting element group. The light emitting elements in the same light emitting element group share a same anode. The first display area has greater light transmittance than the second display area. The photosensitive component is arranged on a side of the first display area away from a display surface. The control chip is configured to at least control the light emitting element to emit light and the photosensitive component to operate.

It can be seen from the above description that in the display panel and the electronic device according to the embodiments of the present application, the display panel is provided with the first display area and the second display area at least partially surrounding the first display area. Further, the light emitting elements arranged in the first display area are grouped into at least the light emitting element group. All the light emitting elements in the same light emitting element group share the same anode, and therefore can be controlled to emit light synchronously via the anode, to scale down a lightproof structure in the first display area and improving the light transmittance of the first display area.

### BRIEF DESCRIPTION OF THE DRAWINGS

The following briefly introduces the drawings to be used in the description of the embodiments or the related technologies in order to more clearly illustrate the embodiments of the present application or related technologies. Apparently, the drawings in the following description show merely some embodiments of the present application.

The structure, scale, size, etc. shown in the drawings of this specification are for the purpose of only matching the content disclosed in the specification for those who are familiar with the technologies to understand and read, rather than limiting the conditions under which the present application is to be implemented, and therefore have no technical significance. Any modification to the structure, change to the scale or the size without affecting the functions and the purpose of the present application shall still fall within the scope covered by the embodiments disclosed in the present application.

FIG. 1 is a top view of a display panel according to an embodiment of the present application;

FIG. 2 is a partially enlarged view of the display panel shown in FIG. 1;

FIG. 3 is a cross-sectional view of the display panel shown in FIG. 2 in a Q-Q′ direction;

FIG. 4 is a cross-sectional view of the display panel according to an embodiment of the present application;

FIG. 5 is a schematic diagram illustrating a layout of light emitting elements in a first display area according to an embodiment of the present application;

FIG. 6 is a schematic diagram illustrating the layout of light emitting elements in the display panel according to an embodiment of the present application;

FIG. 7 is a schematic diagram illustrating the layout of light emitting elements in the first display area according to another embodiment of the present application;

FIG. 8 is a schematic diagram illustrating the layout of light emitting elements in the first display area according to another embodiment of the present application;

FIG. 9 is a schematic diagram illustrating a layout of signal cables in the display panel according to an embodiment of the present application;

FIG. 10 is a sectional view of the display panel shown in FIG. 9 in a D-D′ direction;

FIG. 11 is a schematic diagram illustrating a layout of signal cables in the display panel according to an embodiment of the present application;

FIG. 12 is a sectional view of a second display area in the display panel according to an embodiment of the present application;

FIG. 13 is a schematic diagram illustrating a layout of anodes in the first display area according to an embodiment of the present application;

FIG. 14 is a sectional view of the first display area in the display panel according to an embodiment of the present application;

FIG. 15 is a schematic diagram illustrating the wiring in the first display area in the display panel according to an embodiment of the present application;

FIG. 16 is a schematic structural diagram of an electronic device according to an embodiment of the present application; and

FIG. 17 is a timing diagram for switching on a light emitting element in the first display area and the camera module according to an embodiment of the present application.

### DETAILED DESCRIPTION

The embodiments of the present application are described clearly and completely below with reference to the drawings in the embodiments of the present application. Apparently, the described embodiments are only some rather than all of the embodiments of the present application.

Therefore, the present application intends to cover the modifications and changes of the present application falling within the scope of the claims (the embodiments to be protected) and their equivalents. It should be noted that, the implementations provided in the embodiments of the present application may be combined with each other if no contradiction.

The present application will be further described in detail below in conjunction with the accompanying drawings and specific implementations, in order to make the embodiments of the present application are more comprehensible.

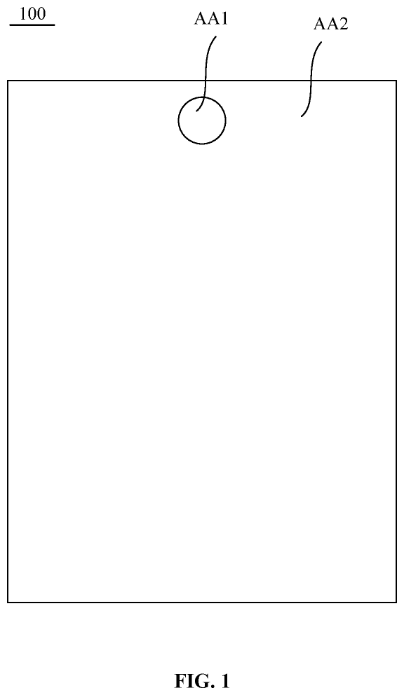

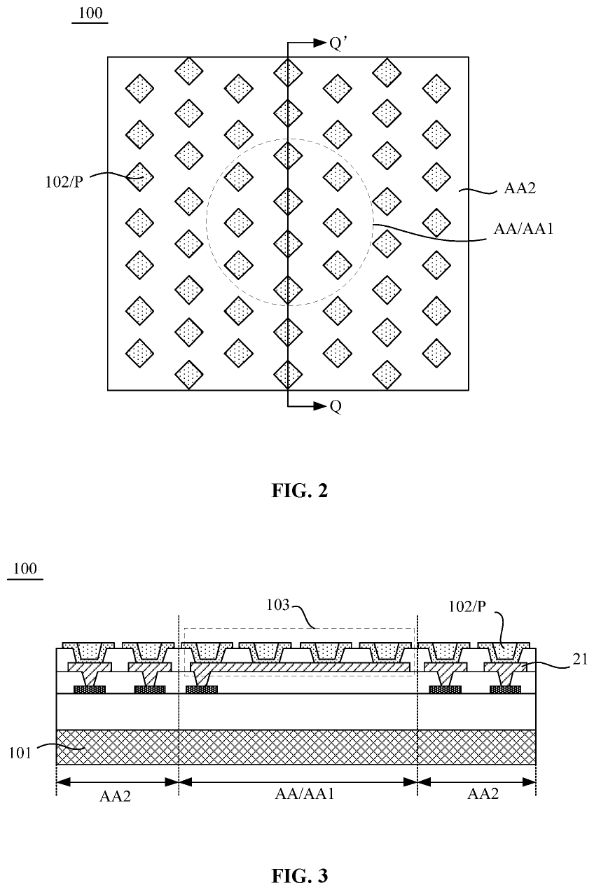

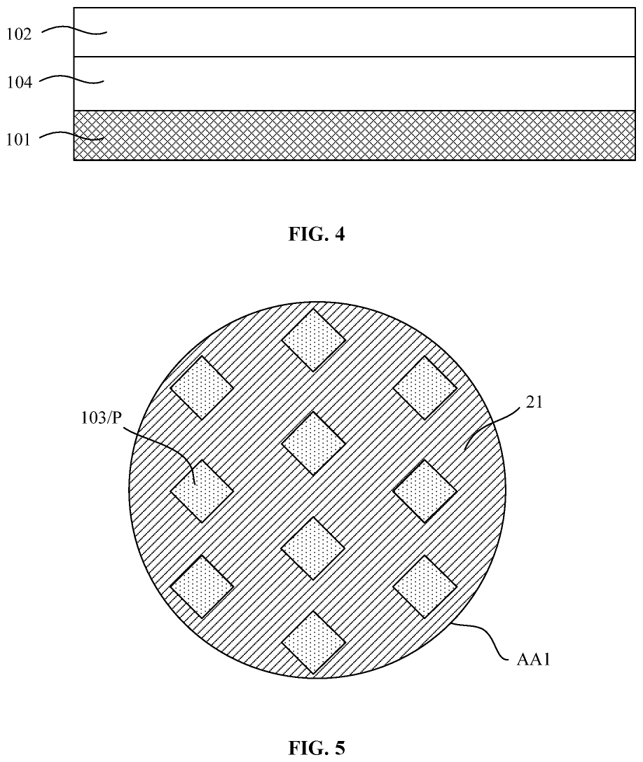

Reference is made to FIG. 1 to FIG. 3. FIG. 1 is a top view of a display panel according to an embodiment of the present application. FIG. 2 is a partially enlarged view of the display panel shown in FIG. 1. FIG. 3 is a cross-sectional view of the display panel shown in FIG. 2 in a Q-Q′ direction. The display panel 100 includes a display area AA. The display area AA includes a first display area AA1 and a second display area AA2. The second display area AA2 at least partially surrounds the first display area AA1. Light transmittance of the first display area AA1 is greater than light transmittance of the second display area AA2.

The display panel 100 further includes a substrate 101, and a display array 102 on the substrate 101. The display array 102 includes light emitting elements P arranged in the display area AA.

The light emitting elements P arranged in the first display area AA1 are grouped into at least one light emitting element group 103. The light emitting elements P in the same light emitting element group 103 share a same anode 21.

The display panel 100 includes the first display area AA1 and the second display area AA2 at least partially surrounding the first display area AA1. The light emitting elements P arranged in the first display area AA1 are grouped into the light emitting element group 103. The light emitting elements P in the same light emitting element group 103 share the same anode 21, and therefore can be controlled to emit light synchronously via the anode 21. In this way, as described below, the light emitting elements P in the same light emitting element group 103 can be controlled to emit light synchronously through a signal cable of the anode and may not be connected to a pixel circuit. Alternatively, the light emitting elements P in the same light emitting element group 103 are connected to the same pixel circuit via the anode 21 shared among them, and therefore can be controlled to emit light synchronously via this pixel circuit. In this way, the number of pixel circuits, and the number of signal cables connected to the pixel circuits in the first display area AA1 can be greatly reduced, to scale down the lightproof structure in the first display area AA1 and improving the light transmittance of the first display area AA1.

The first display area AA1 in the display panel 100 may be circular, rectangular or in other shapes, which is not limited herein.

The second display area AA2 may completely surround the first display area AA1, as shown in FIG. 1 to FIG. 3. In other embodiments, the second display area AA2 partially surrounds the first display area AA1. For example, the first display area AA1 is rectangular inside the second display area AA2, and an upper edge of the first display area AA1 coincides an upper edge of the second display area AA2. Therefore, where the first display area AA1 is arranged in the second display area AA2 and how the second display area AA2 surrounds the first display area AA1 depend on requirements to use the display panel 100, and thus are not limited herein.

The number of light emitting elements P in the first display area AA1 depends on a size of the light emitting element P and the size and the shape of the first display area AA1, and thus is not limited herein.

FIG. 4 is a cross sectional view of the display panel according to an embodiment of the present application. In combination with FIG. 3 and FIG. 4, a circuit layer 104 is arranged between the substrate 101 and the display array 102. The circuit layer 104 includes a pixel circuit and various signal cables connected to the pixel circuit.

The pixel circuit may be any existing pixel circuit, e.g., the pixel circuit composed of 7T1C (seven thin film transistors and one storage capacitor), or the pixel circuit composed of 8T1C (eight thin film transistors and one storage capacitor), and is not limited herein. The signal cables connected to the pixel circuit include a scanning signal cable, a light emission control signal cable, a reference voltage signal cable, a data signal cable, a positive power signal cable, a negative power supply cable and the like.

Both the pixel circuit and the signal cable connected to the pixel circuit are made of metal layer that is lightproof, as a main factor affecting the light transmittance. In order to improve the light transmittance of the first display area AA1, the pixel circuit connected to the light emitting elements P in the first display area AA1 is commonly moved outside the first display area AA1, for example, to a pixel gap between light emitting elements Pin the neighboring second display area AA2. In combination with the solution that the light emitting elements Pin the first display area AA1 share the same anode 21, all the light emitting elements P in the same light emitting element group 103 can share the same pixel circuit, the number of pixel circuits to be connected to the light emitting elements P in the first display area AA1 and the number of signal cables in the first display area AA1 can be greatly reduced, to increase the light transmittance of the first display area AA1.

The pixel circuit connected to the light emitting elements P in the first display area AA1 is moved outside the first display area AA1, which can improve the light transmittance of the first display area AA1 to a certain extent. However, only few pixel circuits in the first display area AA1 moved outside the first display area AA1 due to a fact that various signal cables are arranged in the pixel gap of limited space in the second display area AA2. Therefore, some pixel circuits and the lightproof signal cables connected to these pixel circuits are still arranged in the first display area AA1. Therefore, this solution increases the light transmittance of the first display area AA1 to a limited extent only.

In some embodiments of the present application, the light emitting elements P in the second display area AA2 are connected to the pixel circuit, and therefore are controlled by the pixel circuit to emit light. The light emitting elements P in the first display area AA1 are not connected to the pixel circuit in order to further improve the light transmittance of the first display area AA1. As described below, the first display area AA1 covers relatively less space in the display area AA, and does not necessitate high quality of the displayed image. Therefore, the anode 21 of the light emitting element P in the first display area AA1 is connected to the anode signal cable rather than the pixel circuit, and therefore the light emitting element P is controlled to emit light through the anode signal cable. In this way, it is unnecessary to arrange the pixel circuit and the various lightproof signal cables connected to the pixel circuit in the first display area AA1. Therefore, the transmittance of the first display area AA1 can be greatly improved while the first display area AA1 is still capable of displaying.

The first display area AA1 covers much smaller space than the second display area AA2 in the display area AA, and does not necessitate high quality of the displayed image. In view of this, the anode 21 and the cathode of the light emitting element P in the first display area AA1 are connected to a driving unit located in a marginal area of the display panel 100 through different respective signal cables, and therefore are supplied with an operation voltage by the driving unit directly. In this way, the light emitting element P in the first display area AA1 is not connected to the pixel circuit, therefore it is unnecessary to arrange the pixel circuit and the various lightproof signal cables connected to the pixel circuit in the first display area AA1 for the light emitting elements P.

FIG. 5 is a schematic diagram illustrating a layout of the light emitting elements in the first display area according to the embodiment of the present application. The light emitting elements P in the first display area AA1 all are grouped into one light emitting element group 103, and share the same anode 21. In this way, all the light emitting elements P in the first display area AA1 share the same anode 21 and emit light simultaneously, under simple control.

As shown in FIG. 5, all the light emitting elements in the first display area AA1 can be controlled by one pixel circuit to emit light, and the number of pixel circuits and the signal cables connected to the pixel circuits in the first display area AA1 can be greatly reduced, to improve the light transmittance of the first display area AA1.

As shown in FIG. 5, alternatively, all the light emitting elements P in the first display area AA1 are directly controlled by the driving unit in the marginal area rather than connected to the pixel circuit as mentioned above, to improve the transmittance of the first display area AA1 to a greater extent.

In the case that all the light emitting elements P in the first display area AA1 share the same anode 21, the light emitting elements P in the light emitting element group 103 emit light in at least two different colors. The light emitting elements P emitting light in different colors are different in luminous efficiency. In this case, the light emitting elements P in the light emitting element group 103 that emit light in at least two different colors share the same anode 21, and therefore are controlled to emit light synchronously. In this case, the light emitting elements P emitting light in different colors in the first display area AA1 are controlled to emit light synchronously, and have the same grayscale. In order to display an image in the entire display area AA better, the grayscale of the light emitting element P in the first display area AA1 is set to be identical or approximate to an average grayscale of light emitting elements P in a preset area. The preset area is an area adjacent to the first display area AA1 in the second display area AA2, and depends on requirements. Therefore, the overall display effect in the first display area AA1 is identical or approximate to that in the neighboring area in the second display area AA2.

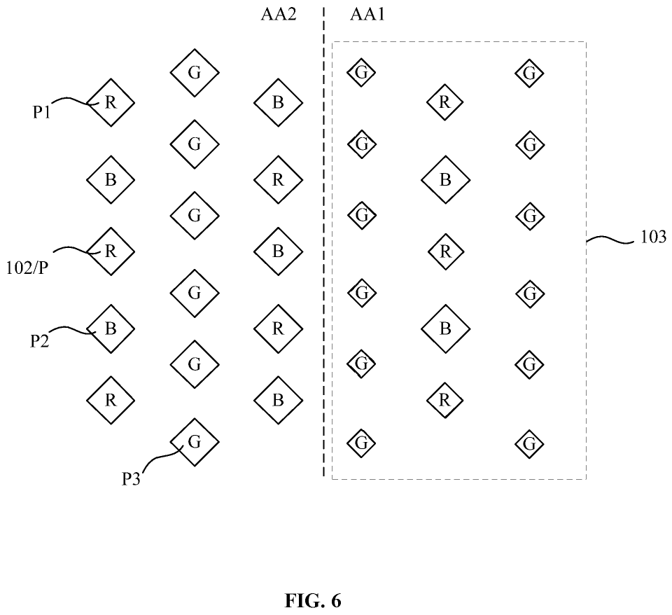

FIG. 6 is a schematic diagram illustrating the layout of light emitting elements in the display panel according to an embodiment of the present application. The light emitting element group 103 and the second display area AA2 both include a first light emitting element P1 and a second light emitting element P1 that emit light in different colors. The luminous efficiency of the first light emitting element P1 is greater than the luminous efficiency of the second light emitting element P2. The opening for the first light emitting element P1 in the first display area AA1 is smaller than the opening for the first light emitting element P1 in the second display area AA2 in size.

The light emitting element P in the normal display area (the second display area AA2) is controlled by the pixel circuit connected to it to emit light. Therefore, the light emitting elements P emitting light in different colors each are provided with an opening corresponding to its luminous efficiency, for better white balance. The light emitting elements P that emit light in different colors in the first display area AA share the same anode 21, and are controlled to emit light synchronously. In this case, if the light emitting element P in the first display area AA is provided with the opening in the same size as the normal display area, the light of different colors may be different in proportion due to the different luminous efficiencies of the light emitting elements P emitting light in different colors, resulting in failure to display the central color.

In the embodiments of the present application, the opening for the first light emitting element P1 in the first display area AA1 is smaller than the opening for the first light emitting element P1 in the second display area AA2 in size. When all the light emitting elements P in the first display area AA1 share the same anode 21, light in different colors are equal in proportion. Therefore, the central color can be successfully displayed in the first display area AA1.

In other embodiments, the light emitting element P in the first display area AA1 and the light emitting element P in the second display area AA2 that emit light in the same color are provided with openings in equal size.

As shown in FIG. 6, the first light emitting element P1 emits light in green G or red R. The second light emitting element P2 emits light in blue B. The light emitting element P in the embodiments of the present application is an OLED (organic light emitting diode). In this case, the light emitting element P that emits light in blue B has the lowest luminous efficiency. As mentioned above in the case that the light emitting element P in the first display area AA1 is provided with the opening in the same size as in the normal display area, since the light emitting elements P emitting light in red R and green G have relatively large luminous efficiency and the light emitting element P emitting light in blue B has relatively small luminous efficiency, the light in red R and green G is greater than blue B in proportion when the light emitting elements P emitting light in different colors in the first display area AA share the same anode 21 and controlled synchronously, resulting in failure to display the central color. With the embodiments of the present application, the opening for the light emitting element P emitting light in green G and/or red R in the first display area AA1 is different from that in the second display area AA2, and light in red R and/or green G is equal or approximate to light in blue B in proportion in the first display area AA. Therefore, the central color can be successfully displayed in the first display area AA1.

All the light emitting elements P in the first display area AA1 that belong to the same light emitting element group 103 and emit light in different colors synchronously may emit light in black, white and other grayscales. In other embodiments, the light emitting elements P emitting light in the same color in the first display area AA1 are in the same light emitting element group 103, and the light emitting elements P emitting light in different colors are in respective light emitting element groups 103, for colorful display in the first display area AA1.

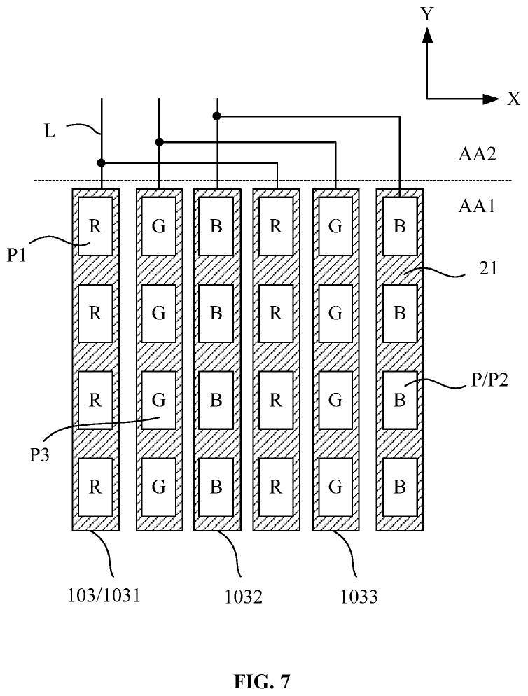

FIG. 7 is a schematic diagram illustrating the layout of light emitting elements in the first display area according to another embodiment of the present application. The first display area AA1 includes at least a first light emitting element group 1031, a second light emitting element group 1032 and a third light emitting element group 1033. The first light emitting element group 1031 includes first light emitting elements P1 that emit light in a first primary color. The second light emitting element group 1032 includes second light emitting element P2 that emit light in a second primary color. The third light emitting element group 1033 includes third light emitting elements P3 that emit light in a third primary color. The anodes 21 in the first light emitting element group 1031, the second light emitting element group 1032 and the third light emitting element group 1033 are connected to different anode signal cables L.

As shown in FIG. 7, in the first display area AA1, the light emitting elements P emitting light in the same color are in the same light emitting element group 103, and the light emitting elements P emitting light in different colors are in respective light emitting element groups 103. In this case, the light emitting elements P emitting light in the same color share the same anode 21, and the light emitting elements P emitting light in different colors are connected to respective anodes 21. Therefore, the light emitting elements P emitting light in the same color can be controlled to emit light simultaneously, and the light emitting elements P emitting light in different colors can be controlled to emit light separately, to achieve colorful display in the first display area AA1.

In some embodiments of the present application, as shown in FIG. 7, light emitting element groups 103 are sequentially arranged in a first direction X in the first display area AA1. The light emitting elements P in the same light emitting element group 103 emit light in the same color and are arranged sequentially in a second direction Y. The anode 21 shared among light emitting elements P is a strip-shaped electrode extending along the second direction Y. Along the first direction X, the light emitting elements P in a light emitting element group 103 emit light in a color different from both neighboring light emitting element groups 103. The first direction intersects with the second direction, and both the first direction and the second direction are parallel to a plane where the substrate is arranged. In these embodiments, the light emitting elements P emitting light in the same color can be controlled to emit light simultaneously, and the light emitting elements P emitting light in different colors can be controlled to emit light separately, to achieve colorful display in the first display area AA1. In one embodiment, in the first display area AA1, the anodes 21 of the light emitting element groups 103 are strip-shaped electrodes distributed in parallel and at intervals, and are simple in structure, facilitating the layout of the anodes 21 in the first display area AA1 and simplifying manufacturing process.

As shown in FIG. 7, the light emitting elements P are arranged in an array in the first display area AA1. The light emitting elements P in different rows are arranged facing each other respectively in the second direction Y (column direction).

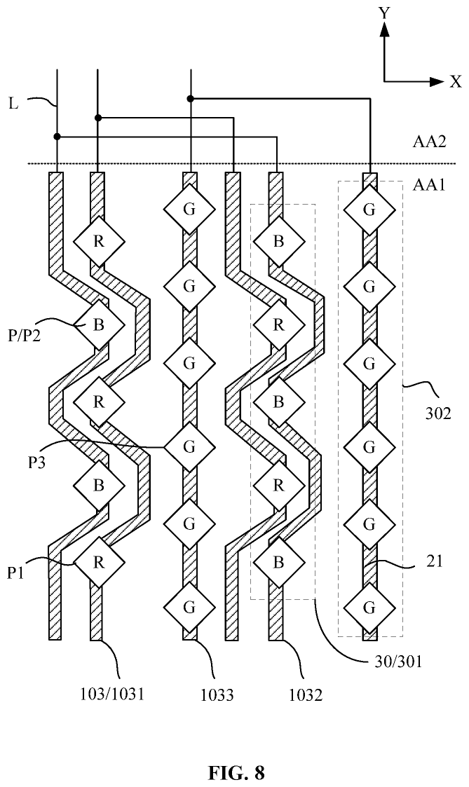

FIG. 8 is a schematic diagram illustrating the layout of light emitting elements in the first display area according to another embodiment of the present application. In this embodiment, the first display area AA1 includes pixel groups 30 sequentially arranged in a first direction X. The pixel group 30 includes light emitting elements P sequentially arranged in a second direction Y. As shown in FIG. 8, a column of light emitting elements P is regarded as a pixel group 30.

Two adjacent pixel groups 30 are respectively a first pixel group 301 and a second pixel group 302. The first pixel group 301 includes a first light emitting element P1 and a second light emitting element P1 arranged alternately in the second direction Y. The second pixel group 302 includes third light emitting elements P3 arranged sequentially in the second direction Y. The first light emitting element P1, the second light emitting element P2 and the third light emitting element P3 emit light in different colors and are in different light emitting element groups 103, respectively. In the first pixel group 301, all the first light emitting elements P1 are in one light emitting element group 103, and all the second light emitting elements P2 are in the other light emitting element group 103. In the second pixel group 302, all the third light emitting elements P3 are in the same light emitting element group 103.

Similar to that shown in FIG. 7, in the embodiment shown in FIG. 8, the light emitting elements P emitting light in the same color can be controlled to emit light simultaneously, and the light emitting elements P emitting light in different colors can be controlled to emit light separately, to achieve colorful display in the first display area AA1. In one embodiment, in the first display area AA1, the anodes 21 of the light emitting element groups 103 are strip-shaped or zigzag electrodes, and are simple in structure, facilitating the layout of the anodes 21 in the first display area AA1 and simplifying manufacturing process.

As shown in FIG. 8, the light emitting elements P in the first display area AA1 are arranged in diamond, and the light emitting elements P in adjacent rows are staggered.

It should be noted that in the embodiments of the present application, the light emitting elements P in the first display area AA1 and the second display area AA2 may be arranged as shown in FIG. 7 or FIG. 8. The light emitting elements P in the first display area AA1 and the light emitting elements P in the second display area AA2 may be arranged identically or differently, which is not limited herein. The shape of the common anode 21 depends on the layout of the light emitting elements P in the first display area AA1. The light emitting elements P in the second display area AA2 are connected to respective single anodes.

In the embodiments of the present application, the light emitting elements P in the same light emitting element group 103 emit light in the same color, and the light emitting elements P in different light emitting element groups 103 emit light in the different colors. The light emitting elements P in the same light emitting element group 103 are arranged sequentially along the second direction Y, and the common anode 21 shared among the light emitting elements P extends along the second direction Y. The anode 21 may be wider or thinner than the light emitting element P in the first direction X, which is not limited herein.

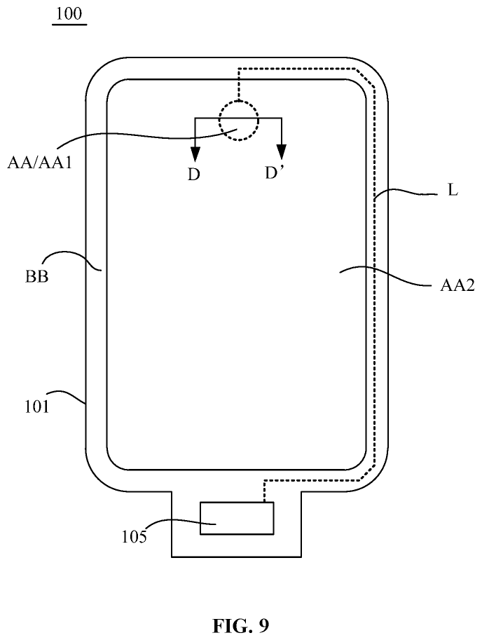

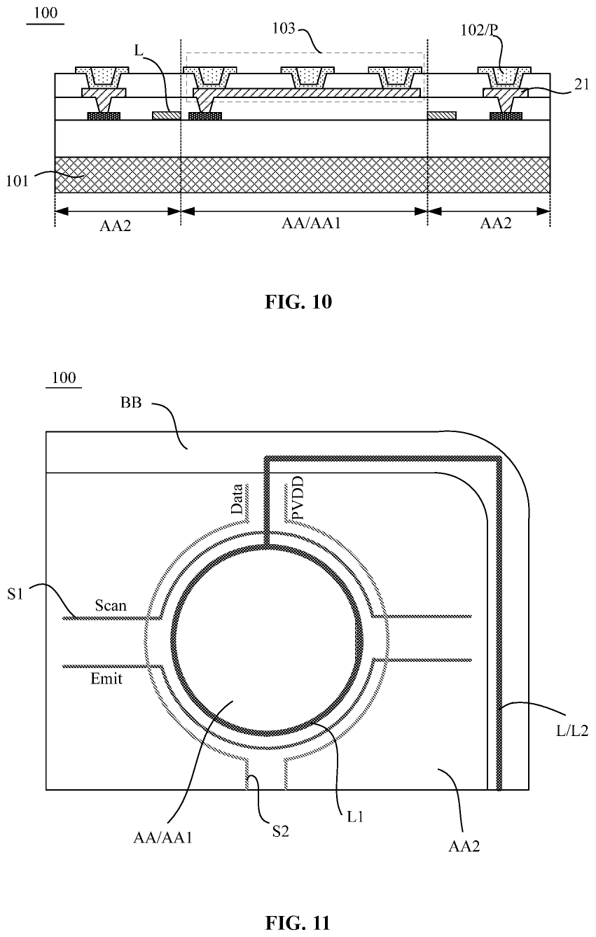

FIG. 9 is a schematic diagram illustrating a layout of signal cables in the display panel according to an embodiment of the present application. FIG. 10 is a sectional view of the display panel shown in FIG. 9 in the D-D′ direction. Based on any of the above embodiments, the display panel 100 shown in FIG. 9 includes a marginal area BB surrounding the second display area AA2, and the marginal area BB includes a binding area 105. An anode signal cable L is arranged between the substrate 101 and the display array 102. The anode 21 of the light emitting element P in the first display area AA1 is connected to one end of the anode signal cable L, and the other end of the anode signal cable L is connect to the binding area 105, and the anode 21 is connected to the binding area 105 through the anode signal cable L rather than connected to the pixel circuit.

As shown in FIG. 9 and FIG. 10, in the display panel according to the embodiment of the present application, the light emitting element P in the first display area AA1 is not connected to the pixel circuit as in the second display area AA2. Instead, the light emitting element Pin the first display area AA1 is directly connected to the binding area 105 through the anode signal cable L. Therefore, the control chip fixedly connected in the binding area 105 can directly control the light emitting element P in the first display area AA1 to emit light. It is unnecessary to arrange a pixel circuit and various signal cables connected to the pixel circuit in the first display area AA1, to improve the light transmittance of the first display area AA1.

As mentioned above, the first display area AA1 is much smaller than the second display area AA2 in size, and has lower requirements on display. In order to increase the light transmittance of the first display area AA1 to a greater extent, the light emitting element P in the first display area AA1 is directly connected to the binding area 105 through the anode signal cable L. Therefore, it is unnecessary to arrange a pixel circuit and various signal cables connected to the pixel circuit in the first display area AA1 for the light emitting element P in the first display area AA1, to improve the light transmittance of the first display area AA1.

As shown in FIG. 4 and FIG. 10, a circuit layer 104 is arranged between the substrate 101 and the display array 102, and the circuit layer 104 includes the pixel circuit and various signal cables connected to the pixel circuit. The anode signal cable L is directly formed by the metal layer in the circuit layer 104, and therefore it is unnecessary to arrange additional metal layer in order to form the anode signal cable L, to thin the display panel.

In some embodiments, as shown in FIG. 9 and FIG. 10, the anode signal cable L extends from the marginal area BB closest to the first display area AA1 to the first display area AA1 to connect to the anode 21 in the first display area AA1. Generally, the first display area AA1 is located at an upper end of the display panel 100, and the binding area 105 is located at a lower end of the display panel 100. In this case, as shown in FIG. 9, the anode signal cable L extends from the upper end of the marginal area BB to the first display area AA1, and extends from the upper end of the marginal area BB and the left or right end of the marginal area BB to the binding area 105 in the lower end of the marginal area BB. In this way, the anode signal cable L can be connected from the marginal area BB to the first display area AA1 along a shortest distance from the marginal area BB, and the distance of the anode signal cable L passing through the display area AA can be minimized, to reduce the influence of the anode signal cable L on the display area AA.

FIG. 11 is a schematic diagram illustrating a layout of signal cables in the display panel according to an embodiment of the present application. In combination with FIG. 9 to FIG. 11, the anode signal cable L in the display panel 100 includes: a ring part L1 surrounding the first display area AA1, and a wiring part L2 extending from the binding area 105 to an edge of the first display area AA1. The anode 21 of the light emitting element Pin the first display area AA1 is connected to the ring part L1. The wiring part L2 is connected to the ring part L1.

In the first display area AA1, both ends of the anode 21 shared among the light emitting elements P are connected to the ring part L1 in the direction along which the anode 21 extends, in order to reduce a voltage drop on the anode 21, to balance brightness of the light emitting elements P in the same light emitting element group 103.

In the second display area AA2, the light emitting elements P have respective anodes 21 that are independent of each other and connected to the pixel circuit. The light emitting elements P are controlled by the pixel circuit to emit light. The pixel circuit is connected to signal cables. Two parts of the signal cable connected to the pixel circuit separated by the first display area AA1 are connected together through an arc-shaped part surrounding the first display area AA1, and the signal cable bypasses the first display area AA1.

The signal cables connected to the pixel circuit include a first signal cable S1 extending along the first direction X and a second signal cable S2 extending along the second direction. The first signal cable S1 includes a scanning signal cable for inputting a scanning signal Scan and a light emitting signal cable for inputting a light emitting signal Emit. The second signal cable S2 includes a data signal cable for inputting an input data signal Data and a positive power signal cable for inputting a positive power signal PVDD.

As shown in FIG. 11, each of the first signal cable S1 and the second signal cable S2 bypassing the first display area AA1 includes an arc-shaped part. The signal cable segments of the first signal cable S1 that are separated by the first display area AA1 are connected together by the arc-shaped curved part surrounding the first display area AA1. The signal cable segments of the second signal cable S2 that are separated by the first display area AA1 are connected together by the arc-shaped curved part surrounding the first display area AA1.

All the light emitting elements P in the first display area AA1, when sharing the same anode 21, are provided with anode signals through one anode signal cable L. When there are anodes 21 in the first display area AA1, anode signals are provided to the anodes 21 through anode signal cables L connected to the anodes 21, respectively. For example, when the light emitting elements P emitting light in different colors in the first display area AA1 are in different light emitting element groups 103, and the light emitting elements P emitting light in the same color are in the same light emitting element group 103, the anodes 21 of the light emitting elements P are connected to anode signal cables L respectively.

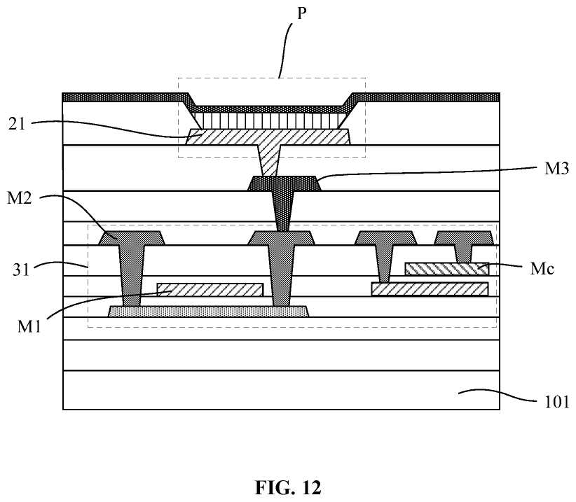

FIG. 12 is a sectional view of the second display area in the display panel according to an embodiment of the present application. In combination with FIG. 4, FIG. 9 and FIG. 12, the light emitting element P in the second display area AA is connected a pixel circuit 31. The pixel circuit 31 is arranged between the display array 102 and the substrate 101, and is arranged in the second display area AA2. A gate electrode of the thin film transistor in the pixel circuit 31 is in the first metal layer M1, and a source electrode and a drain electrode of the thin film transistor are in the second metal layer M2. The first metal layer M1 is arranged between the second metal layer M2 and the substrate 101. A third metal layer M3 is arranged between the second metal layer M2 and a conduction layer where the anode 21 is arranged. A fourth metal layer Mc is arranged between the first metal layer M1 and the second metal layer M2. At least one of the first metal layer M1 to the fourth metal layer Mc includes the anode signal cable L. In this way, the anode signal cable L is formed directly by an existing metal layer in the display panel 100, and therefore it is unnecessary to arrange additional metal layer in order to form the anode signal cable L, to thin the display panel 100.

As mentioned above, the circuit layer 104 includes the pixel circuit 31, and the pixel circuit 31 includes the thin film transistor and the storage capacitor. FIG. 12 illustrates only the thin film transistor and the storage capacitor formed by the first metal layer M1 and the fourth metal layer Mc in the pixel circuit 31 without other elements in the pixel circuit 31.

As shown in FIG. 10 and FIG. 12, the third metal layer M3 includes the anode signal cable L, i.e., the anode signal cable L is directly made of the third metal layer M3. Therefore, it is unnecessary to arrange additional metal layer in order to form the anode signal cable L, to thin the display panel. In other embodiments of the present application, the second metal layer M2 includes the anode signal cable L, i.e., the anode signal cable L is directly made of the second metal layer M2, and therefore it is unnecessary to arrange additional metal layer in order to form the anode signal cable L, to thin the display panel.

The anode signal cable L includes a first part arranged in the display area AA and a second part arranged in the marginal area BB. The first part of the anode signal cable L arranged in the display area AA and the second part arranged in the marginal area BB may be arranged in the same metal layer or different metal layers. When the first part of the anode signal cable L arranged in the display area AA and the second part arranged in the marginal area BB are arranged in different metal layers, the two parts may be connected together through a conduction hole.

In the second display area AA2, the anode 21 of the light emitting element P is made of a lightproof metal layer, so as to reduce the resistance of the anode 21 and increase the luminance of the light emitting element P.

In some embodiments of the present application, the anode 21 in the first display area AA1 is a transparent electrode. The light emitting element P in the first display area AA1 has the transparent anode, and the light transmittance of the first display area AA1 can be improved. Here, the anode 21 of the light emitting element Pin the first display area AA1 may be made of transparent conductive materials, e.g., ITO (indium tin oxide).

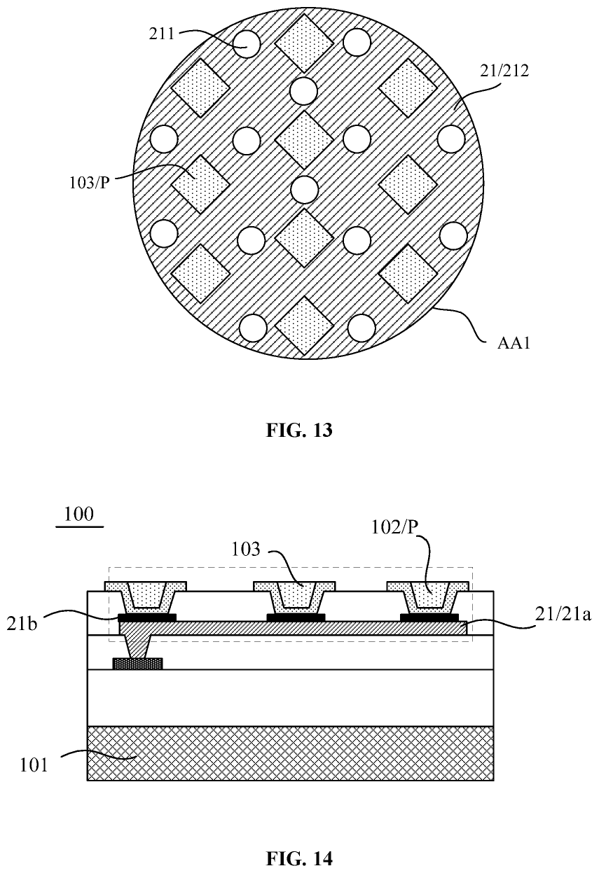

FIG. 13 is a schematic diagram illustrating a layout of anodes in the first display area according to the embodiment of the present application. Here, the light emitting elements P in the first display area AA1 all share the same anode 21, and the anode 21 includes a hollow area 211 and a non-hollow area 212. The non-hollow area 212 overlaps the light emitting element P. In this embodiment, all the light emitting elements P in the first display area AA1 share the same anode 21 which is set to transparent, to improve the light transmittance of the first display area AA1. Since the common transparent conductive materials has certain but low light transmittance, the anode 21 in the first display area AA1 is defined with the hollow area 211 in order to further improve the light transmittance of the first display area AA1.

In some embodiments of the present application, the anode 21 in the first display area AA1 is lightproof. In this case, anodes 21 separate from each other are arranged in the first display area AA1. There is a gap between anodes 21 in order to improve the light transmittance of the first display area AA1. Furthermore, the anode 21 is provided with a hollow area not overlapping the light emitting element P, so as to further increase the light transmittance of the first display area AA1.

In the embodiments of the present application, the light emitting elements P in the same light emitting element group 103 share the same anode 21, and therefore are controlled to emit light synchronously. Furthermore, at least ten light emitting elements P are included in the same light emitting element group 103. Therefore, at least ten light emitting elements P share the anode 21, to simplify the wiring in the first display area AA1 so as to increase the light transmittance of the first display area AA1.

FIG. 14 is a cross-sectional view of the first display area in the display panel according to an embodiment of the present application. In the light emitting element group 103, a part of the anode overlapping the light emitting element P is lightproof, and another part of the anode arranged between adjacent light emitting elements P is transparent. In the light emitting element group 103, the light emitting elements P share the anode 21 which includes a lightproof part overlapping the light emitting element P and a transparent part not overlapping the light emitting element P. The part of the anode 21 that does not overlap the light emitting element P transmits light, and the light transmittance of the first display area AA1 can be improved. The part of the anode 21 that overlaps the light emitting element P is lightproof, to prevent the light emitted by the light emitting element from going out toward the substrate 101 and thence being reflected by the metal layer under the light emitting element P to affect the display effects.

In some embodiments, the anode 21 in the first display area AA1 includes a transparent conductive layer and a lightproof conductive layer that are stacked. The lightproof conductive layer is arranged facing the light emitting element P, and the part of the anode 21 overlapping the light emitting element P is lightproof, and the part of the anode 21 that does not overlap the light emitting element P can transmit light.

In the embodiments of the present application, all the light emitting elements P in the same light emitting element group 103 share the anode 21, and therefore are controlled to emit light synchronously. In one embodiment, the light emitting element P arranged in the first display area AA1 is not connected to the pixel circuit in order to improve the light transmittance of the first display area AA1. Instead, the light emitting element P arranged in the first display area AA1 is directly connected to the anode signal cable L in order to be controlled to emit light. In this case, the display in the first display area AA1 is different form the display in the second display area AA2.

In some embodiments of the present application, the light emitted by the light emitting element P in the first display area AA1 is regulated based on the light emitted by the light emitting element P adjacent to the first display area AA1 in the second display area AA2 in the display panel 100, in order to reduce the difference between the display in the first display AA1 and the display in the second display area AA2.

The light emitted by the light emitting element P in the first display area AA1 is regulated based on the light emitted by the light emitting element P adjacent to the first display area AA1 in the second display area AA2 in at least two manners.

In a first manner, the grayscale of the light emitting element P in the first display area AA1 is regulated based on the grayscale of the light emitting element P adjacent to the first display area AA1 in the second display area AA2 so as to regulate the brightness of the first display area AA1. Therefore, the first display area AA1 has the same brightness as or similar brightness to the part of the second display area AA2 adjacent to the first display area AA1, to avoid significance brightness difference at the demarcation between the first display area AA1 and the second display area AA2.

In a second manner, the chrominance of the light emitting element P in the first display area AA1 is regulated based on the chrominance of the light emitting element P adjacent to the first display area AA1 in the second display area AA2, and the first display area AA1 has the same chrominance as or similar chrominance to the part of the second display area AA2 adjacent to the first display area AA1, to avoid significance chrominance difference at the demarcation between the first display area AA1 and the second display area AA2.

In some embodiments of the present application, in the first display area AA1, light emitting elements P emitting light in the same color, i.e., all the light emitting elements P in the light emitting element group 103, share the same anode 21, and therefore are controlled to emit light synchronously. In one embodiment, the light emitting elements P in the first display area AA1 emitting light in at least two different colors, i.e., the light emitting elements P in the light emitting element group 103, share the same anode 21, and therefore are controlled to emit light simultaneously.

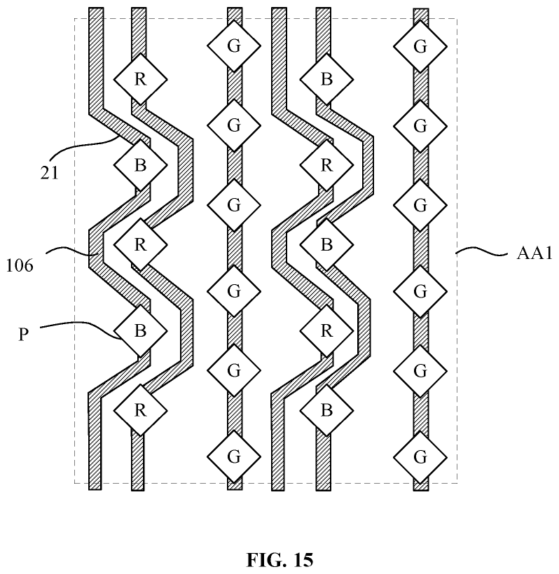

FIG. 15 is a schematic diagram illustrating the wiring in the first display area in the display panel according to the embodiment of the present application. The first display area AA1 includes a connection cable 106 connected to the anode 21 of the light emitting element P. In a direction perpendicular to the plane where the substrate 101 is arranged, the connection cable 106 overlaps light emitting elements P, and the light emitting elements P overlapping the same connection cable 106 emit light in the same color.

In the embodiment shown in FIG. 15, the anode 21 in the first display area AA1 is supplied with an operation voltage through the connection cable 106. A conductive layer where the connecting wire 106 is arranged is arranged between the substrate 101 and the anode 21.

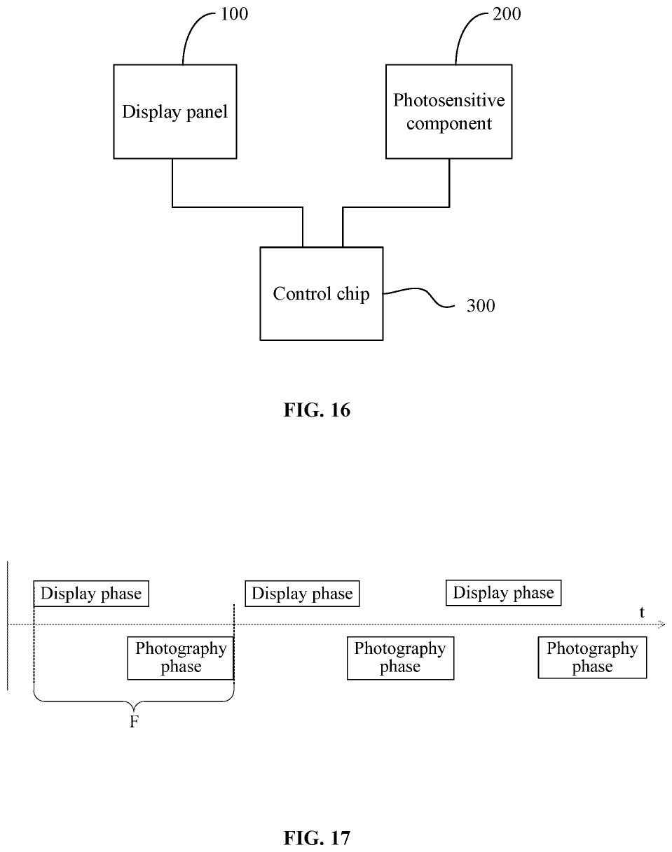

Based on the foregoing embodiments, an electronic device is further provided according to another embodiment of the present application, as shown in FIG. 16.

FIG. 16 is a schematic structural diagram of the electronic device according to an embodiment of the present application. In combination with FIG. 1 to FIG. 3 and FIG. 16, the electronic device includes the display panel 100, a photosensitive component 200, and a control chip 300.

The display panel 100 includes a display area AA, a substrate 101 and a display array 102. The display area AA includes a first display area AA1 and a second display area AA2 at least partially surrounding the first display area AA1. The photosensitive component 200 is arranged on a side of the first display area AA1 away from a display surface. light emitting elements P are arranged in the display array 1021, and are distributed between the first display area AA1 and the second display area AA2. The light emitting elements P in the first display area AA1 are grouped into at least one light emitting element group 103. The light emitting elements P in the same light emitting element group 103 share the same anode 21. The first display area AA1 has greater light transmittance than the second display area AA2.

The control chip 300 is configured to control the light emitting element P to emit light and control the photosensitive component 200 to operate.

In the embodiments of the present application, the electronic device is capable of displaying objects. For example, the electronic device is a mobile phone, a tablet computer, and a smart wearable device. The electronic device equipped with the display panel 100 where the light transmittance of the first display area AA1 is greatly improved has increased amount of ambient light incident on the photosensitive element 200.

In some embodiments, the photosensitive component 200 is a camera module. The control chip 300 is configured to control the light emitting element P in the first display area AA1 and the camera module to be on alternately in a period. The timing for controlling the light emitting element P in the first display area AA1 and the camera module is shown in FIG. 17.

FIG. 17 is a timing diagram for switching on the light emitting element in the first display area and the camera module according to the embodiment of the present application. One frame F for the display panel 100 includes a display phase and a photography phase that are staggered. Display phases alternate with photography phases throughout all the frames F. The light emitting element P is on and the camera module is off in the display phase. The light emitting element P is off and the camera module is on in the photography phase.

In the embodiments of the present application, the light emitting element P in the first display area AA1 and the camera module are on alternately. The image display in the first display area AA1 and image acquisition by the camera module are staggered, to prevent the light emitting element P in the first display area AA1 from emitting light simultaneously with the image acquisition by the camera module and consequently interfering with the image acquisition, and further achieving full-screen image display image due to persistence of vision when the first display area AA1 displays the image in the period.

The light emitting element P in the first display area AA1 and the camera module are on alternately in one period. The duration in which one of the light emitting element P and the camera module is on is an integral multiple of the duration in which the other is on in order to facilitate division of the frame F, to simplify the timing for controlling the display panel 100.

The electronic device according to the embodiments of the present application includes the above display panel 100. Referring to the drawings, the display panel 100 includes the light emitting element group 103 arranged in the first display area AA1, and the light emitting elements P in the light emitting element group 103 share the same anode 21 and therefore are controlled to emit light synchronously.

The first display area AA1 performs display in the photography phase. In this case, the control chip 300 regulates the light emitted by the light emitting element P in the first display area AA1 based on the display in a part of the second display area AA2 adjacent to the first display area AA1 as follows.

Firstly, the control chip 300 acquires a to-be-displayed parameter of a light emitting element Pin the part of the second display area AA2 adjacent to the first display area AA1. The part of the second display area AA2 adjacent to the first display area AA1 depends on requirements, and is not limited herein.

Then, the control chip 300 determines a display parameter of the light emitting element Pin the first display area AA1 based on the acquired to-be-displayed parameter, and controls the light emitting elements P in the first display area AA1 to emit light based on the determined display parameter.

The parameter herein includes at least one of grayscale and chrominance.

In the embodiments of the present application, the control chip 300 regulates the light emitted by the light emitting element P in the first display area AA1 based on the display in a part of the second display area AA2 adjacent to the first display area AA1, to reduce the difference between the display in the first display area AA1 and the display in the second display area AA2 during the photography.

In other embodiments, the photosensitive component 200 is the camera module. The control chip 300 controls the camera module to be on and the first display area AA1 to not perform the display throughout the period, to facilitate better photographing effect.

The embodiments in this specification are described in a progressive, or parallel, or a combination of progressive and parallel manner. Each embodiment highlights the differences from the other embodiments. For the same and similar parts in various embodiments, reference is made to each other. The device disclosed in the embodiments corresponds to the method disclosed in the embodiments, and therefore is described briefly, and reference is made to the description of the method for relevant parts.

It should be noted that the drawings and the embodiments in the description of the present application are illustrative rather than restrictive. Like reference numerals identify like structures throughout the embodiments in this specification. In addition, for understanding and ease of description, some layers, films, panels, and areas may be exaggerated in thickness in the drawings. It should further be understood that an element such as a layer, film, area, or substrate referred to as being “on” another element may be directly or indirectly on the other element. In addition, “on” means to arrange one element on or under another, rather than essentially means to arrange one element on another according to the direction of gravity.

The orientation or positional relationship indicated by terms “upper”, “lower”, “top”, “bottom”, “inner”, “outer”, etc. are based on the orientation or positional relationship shown in the drawings, and are only for the convenience of describing the present application and a simplified description instead of indicating or implying that the device or element must be arranged, constructed or operated to a particular orientation, and therefore should not be construed as limiting the present application. A component that is considered to be “connected to” another component may be directly or indirectly connected to the other component.

It should also be noted that relational terms herein such as first and second etc. are only for distinguishing one entity or operation from another instead of necessarily requiring or implying such actual relationship or order between these entities or operations. Moreover, the term “comprising”, “including” or any other variation thereof is intended to be non-exclusive, and an article or device comprising a set of elements includes not only those elements but also other elements not expressly listed, or also include elements inherent in the article or device. Without further limitations, an element defined by the phrase “comprising a . . . ” does not exclude the presence of additional identical elements in an article or device comprising this element.

What is claimed is:

1. A display panel, comprising:
a display area, wherein the display area comprises a first display area and a second display area at least partially surrounding the first display area, and the first display area has greater light transmittance than the second display area;
a substrate; and
a display array arranged on the substrate, wherein the display array comprises light emitting elements arranged in the display area, the light emitting elements arranged in the first display area are grouped into at least one light emitting element group, and the light emitting elements in the same light emitting element group share a same anode.

2. The display panel according to claim 1, wherein
all the light emitting elements arranged in the first display area are grouped into one light emitting element group and share the same anode.

3. The display panel according to claim 2, wherein
the light emitting elements in the light emitting element group are configured to emit light in at least two different colors, wherein the light emitting elements configured to emit light in different colors are different in luminous efficiency.

4. The display panel according to claim 3, wherein
the light emitting elements in the light emitting element group and the light emitting elements arranged in the second display area both comprise a first light emitting element and a second light emitting element that are configured to emit light in different colors, the first light emitting element has greater luminous efficiency than the second light emitting element, and the first light emitting element in the light emitting element group is provided with a larger opening than the first light emitting element in the second display area.

5. The display panel according to claim 4, wherein
the first light emitting element is configured to emit light in green or red, and the second light emitting element is configured to emit light in blue.

6. The display panel according to claim 1, wherein the at least one light emitting element group comprises at least a first light emitting element group, a second light emitting element group and a third light emitting element group, wherein
the light emitting elements in the first light emitting element group are all first light emitting elements configured to emit light in a first primary color;
the light emitting elements in the second light emitting element group are all second light emitting elements configured to emit light in a second primary color; and
the light emitting elements in the third light emitting element group are all third light emitting elements configured to emit light in a third primary color, wherein the anode in the first light emitting element group, the anode in the second light emitting element group and the anode in the third light emitting element group are connected to respective anode signal cables.

7. The display panel according to claim 6, wherein
the first, second and third light emitting element groups are arranged sequentially in a first direction;
the light emitting elements in each of the first, second and third light emitting element groups are arranged sequentially in a second direction, and the anode shared among the light emitting elements in the same light emitting element group is a strip-shaped electrode extending along the second direction; and
along the first direction, the light emitting elements in one of the light emitting element groups are configured to emit light in the color different from both of the neighboring light emitting element groups, wherein the first direction intersects with the second direction, and both the first direction and the second direction are parallel to a plane where the substrate is arranged.

8. The display panel according to claim 6, wherein
the light emitting elements arranged in the first display area are grouped into at least a first pixel group and a second pixel group sequentially arranged in a first direction, and the light emitting elements in the same pixel group are arranged sequentially in a second direction; and
the first pixel group is adjacent to the second pixel group, the first light emitting elements and the second light emitting elements are grouped into the first pixel group and the first light emitting elements alternate with the second light emitting elements in the second direction, and the third light emitting elements are grouped into the second pixel group.

9. The display panel according to claim 1, wherein the display panel further comprises:
a marginal area surrounding the second display area, wherein the marginal area comprises a binding area, an anode signal cable is arranged between the substrate and the display array, and the anode is connected to one end of the anode signal cable and the other end of the anode signal cable is connected to the binding area for the anode to be connected to no pixel circuit.

10. The display panel according to claim 9, wherein the anode signal cable comprises:
a ring part surrounding the first display area, wherein the anode is connected to the ring part; and
a wiring part extending from the binding area to an edge of the first display area, wherein the wiring part is connected to the ring part.

11. The display panel according to claim 9, wherein
the light emitting element in the second display area is connected to a pixel circuit, and the pixel circuit is arranged between the display array and the substrate and is in the second display area;
a gate electrode of a thin film transistor in the pixel circuit is arranged in a first metal layer, and a source electrode and a drain electrode of the thin film transistor are arranged in a second metal layer, the first metal layer is arranged between the second metal layer and the substrate, a third metal layer is arranged between the second metal layer and a conductive layer where the anode is arranged, a fourth metal layer is arranged between the second metal layer and the first metal layer; and
the anode signal cable is made of at least one of the first metal layer, the second metal layer, the third metal layer and the fourth metal layer.

12. The display panel according to claim 9, wherein
the anode signal cable extends from the marginal area closest to the first display area to the first display area to be connected to the anode.

13. The display panel according to claim 1, wherein the anode is a transparent electrode.

14. The display panel according to claim 13, wherein
all the light emitting elements in the first display area share the same anode, the anode comprises a hollow area and a non-hollow area, and the non-hollow area overlaps the light emitting elements.

15. The display panel according to claim 1, wherein
at least ten light emitting elements are grouped into the same light emitting element group.

16. The display panel according to claim 1, wherein
in the light emitting element group, a first part of the anode overlapping the light emitting elements is lightproof, and a second part of the anode between adjacent light emitting elements is transparent.

17. The display panel according to claim 1, wherein
the display panel is configured to regulate light to be emitted by the light emitting element in the first display area based on light to be emitted by the light emitting element adjacent to the first display area in the second display area.

18. The display panel according to claim 1, wherein
the light emitting elements in the first display area configured to emit light in a same color share the same anode; or
the light emitting elements in the first display area configured to emit light in at least two colors share the same anode.

19. The display panel according to claim 1, wherein
a connection cable connected to the anode is arranged in the first display area; and
the connection cable overlaps the light emitting elements in a direction perpendicular to a plane where the substrate is arranged, and the light emitting elements overlapping the same connection cable are configured to emit light in a same color.

20. An electronic device, comprising:
a display panel, wherein the display panel comprises:
a display area, wherein the display area comprises a first display area and a second display area at least partially surrounding the first display area, and the first display area has greater light transmittance than the second display area;
a substrate; and
a display array arranged on the substrate, wherein the display array comprises light emitting elements arranged in the display area, the light emitting elements arranged in the first display area are grouped into at least one light emitting element group and the light emitting elements in the same light emitting element group share a same anode;
a photosensitive component arranged on a side of the first display area away from a display surface; and
a control chip configured to at least control the light emitting element to emit light and the photosensitive component to operate.

21. The electronic device according to claim 20, wherein the photosensitive component is a camera module, and wherein the control chip is configured to switch on the light emitting element in the first display area and the camera module alternately in a period.

22. The electronic device according to claim 21, wherein
a duration in which one of the light emitting element and the camera module is on is an integral multiple of a duration in which the other is on, in the period.

23. The electronic device according to claim 20, wherein the photosensitive component is a camera module, and wherein
the control chip is configured to control the camera module to be on and the first display area to not perform display throughout a period.
